(19) United States
(12) Patent Application Publication
(10) Pub. No.: US 2026/0112432 A1
(43) Pub. Date: Apr. 23, 2026

(54) SEMICONDUCTOR STORAGE DEVICE, PRINTING HEAD, AND DATA WRITING METHOD

(71) Applicant: CANON KABUSHIKI KAISHA, Tokyo (JP)

(72) Inventors: TOSHIO NAKANO, Tokyo (JP); YOJI SHIMOYAMA, Kanagawa (JP); TOSHIO NEGISHI, Kanagawa (JP)

(21) Appl. No.: 19/362,089

(22) Filed: Oct. 17, 2025

(30) Foreign Application Priority Data
Oct. 23, 2024 (JP) 2024-186544

(51) Int. Cl. G11C 17/16; G11C 5/06; G11C 5/14; G11C 17/14

(52) U.S. Cl. CPC G11C 17/16; G11C 5/063; G11C 5/14; G11C 17/146

(57) ABSTRACT

Provided is a storage device including a first antifuse element and a second antifuse element, and a supply line extending from a single power supply is branched into supply lines so that the respective supply lines are connected to the first antifuse element and the second antifuse element. A control circuit causes a voltage application to the first antifuse element and a voltage application to the second antifuse element to be alternately performed.

### BACKGROUND

### Field of the Technology

The aspect of the embodiments relates to a semiconductor storage device including an antifuse element, a printing head, and a data writing method.

### Description of the Related Art

As a semiconductor storage device, there is a one time programmable (OTP) memory that uses a polyfuse element or an antifuse element. The antifuse element provides a more stable written state than that of the polyfuse element, but has a write cycle time longer (for example, about ten times longer) than that of the polyfuse element, and hence productivity may be reduced. In view of this, in semiconductor storage devices including antifuse elements, in order to increase a cycle rate through shortening of the write cycle time, there has been studied a two-bit write operation in which antifuse elements corresponding to two bits which are connected to a single power supply are simultaneously written.

In Japanese Patent Laid-Open No. 2010-170609, there is described a semiconductor storage device including antifuse elements. In this semiconductor storage device, a memory cell array in which memory cells including antifuse elements are arranged is divided into two memory banks. Two booster circuits generate write and read voltages to be supplied to the antifuse elements in the respective memory banks. During writing, one bit line for simultaneous writing is selected in each memory bank. Writing is simultaneously performed on the antifuse elements selected in the respective memory banks.

Through repeated turning on and off of a voltage application to the antifuse element at high speed, a gate oxide film between two electrodes of the antifuse element undergoes dielectric breakdown, thereby bringing the antifuse element into a conductive state. Due to individual differences among antifuse elements, the number of times that the voltage application is turned on and off which is for conduction may vary depending on the antifuse element. For that reason, when a voltage is simultaneously applied to two antifuse elements connected to a single power supply in order to simultaneously write two bits, one of the antifuse elements may become conductive first. As a result, a current is caused to more easily flow into the antifuse element that has become conductive first, and it thereby becomes more difficult for a current required for conduction to flow into the other antifuse element, resulting in a write error. This leads to an issue in that a stable written state cannot be provided.

In the semiconductor storage device as described in Japanese Patent Laid-Open No. 2010-170609, a one-bit write operation is performed in each memory bank, and hence the write cycle time is long, thereby causing an issue of reduction in productivity. It is possible to suppress the reduction in productivity by performing the two-bit write operation in each memory bank. However, in that case, the above-mentioned issue of a write error arises.

### SUMMARY

According to the aspect of the embodiments, there is provided a storage device including: a first antifuse element and a second antifuse element, the storage device being configured such that a supply line extending from a single power supply is branched into supply lines so that the respective supply lines are connected to the first antifuse element and the second antifuse element; and a control circuit configured to cause a voltage application to the first antifuse element and a voltage application to the second antifuse element to be alternately performed.

Features of the disclosure will become apparent from the following description of embodiments with reference to the attached drawings. The following description of embodiments is described by way of example.

### BRIEF DESCRIPTION OF THE DRAWINGS

FIG. 1 is a schematic diagram for illustrating a configuration of a semiconductor storage device according to a first embodiment of the disclosure.

FIG. 2 is a timing chart for illustrating a relationship among a pulse signal, a gate voltage of a first switch element, and an applied voltage to a first antifuse element.

FIG. 3 is a timing chart for illustrating a relationship among the pulse signal, a gate voltage of a second switch element, and an applied voltage to a second antifuse element.

FIG. 4 is a timing chart for illustrating a relationship among the pulse signal, the applied voltage to the first antifuse element, and the applied voltage to the second antifuse element.

FIG. 5 is a timing chart of a two-bit write operation in a comparative example.

FIG. 6 is a schematic diagram for illustrating a configuration of a semiconductor storage device according to a second embodiment of the disclosure.

FIG. 7 is a perspective view of a printing head equipped with the semiconductor storage device according to the disclosure.

FIG. 8 is a schematic diagram for illustrating a configuration of an element substrate.

### DESCRIPTION OF THE EMBODIMENTS

Embodiments of the disclosure are described below in detail with reference to the drawings. However, the embodiments are merely exemplification, and are not intended to limit a scope of the disclosure thereto.

### First Embodiment

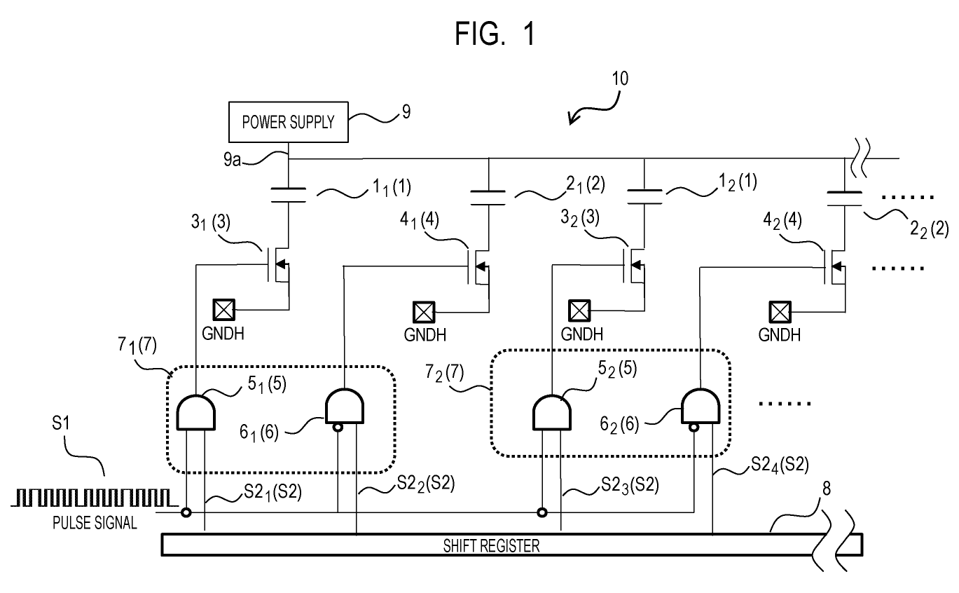

FIG. 1 is a schematic diagram for illustrating a configuration of a semiconductor storage device according to a first embodiment of the disclosure. A semiconductor storage device 10 according to this embodiment includes a first antifuse element 1, a second antifuse element 2, and a control circuit 7. The semiconductor storage device 10 is configured such that a supply line 9a extending from a single power supply (power supply circuit 9) is branched into supply lines so that the respective supply lines are connected to the first antifuse element 1 and the second antifuse element 2 and that a voltage is selectively applied to the first antifuse element 1 and the second antifuse element 2. The control circuit 7 causes a voltage application to the first antifuse element 1 and a voltage application to the second antifuse element 2 to be alternately performed. A two-bit write operation is performed through those voltage applications to the first antifuse element 1 and the second antifuse element 2.

As illustrated in FIG. 1, "n" first antifuse elements 1₁ to 1ₙ are provided as the first antifuse elements 1, and "n" second antifuse elements 2₁ to 2ₙ are provided as the second antifuse elements 2. Those first antifuse elements 1₁ to 1ₙ and second antifuse elements 2₁ to 2ₙ form a 2n-bit memory. The value "n" can be set as appropriate depending on data to be written. The first antifuse elements 1₁ to 1ₙ and the second antifuse elements 2₁ to 2ₙ all have the same structure, and the first antifuse elements and the second antifuse elements are arranged alternately from the left side of the figure. The first antifuse elements 1₃ to 1ₙ and the second antifuse elements 2₃ to 2ₙ are not shown in the figure.

One end of each of the first antifuse elements 1₁ to 1ₙ and the second antifuse elements 2₁ to 2ₙ is connected to the supply line 9a extending from the power supply circuit 9. A first switch element 3₁ is connected in series to the first antifuse element 1₁. In the same manner, first switch elements 3₂ to 3ₙ are connected in series to the first antifuse elements 1₂ to 1ₙ, respectively. A second switch element 4₁ is connected in series to the second antifuse element 2₁. In the same manner, second switch elements 4₂ to 4ₙ are connected in series to second antifuse elements 2₂ to 2ₙ, respectively. The other ends of the first antifuse elements 1₁ to 1ₙ are connected to GND terminals (ground potential terminals) through the first switch elements 3₁ to 3ₙ, respectively. The other ends of the second antifuse elements 2₁ to 2ₙ are connected to GND terminals (ground potential terminals) through the second switch elements 4₁ to 4ₙ, respectively.

The first switch elements 3₁ to 3ₙ and the second switch elements 4₁ to 4ₙ are, for example, metal-oxide-semiconductor (MOS) type field-effect transistors (FETs). The MOSFETs are of two types, namely, n-type MOS (n-MOS) and p-type MOS (p-MOS), and any one thereof may be used. It is easier to handle n-MOSs in terms of circuits than p-MOSs, and hence, in this embodiment, n-type MOS (n-MOS) switch elements are used as the first switch elements 3₁ to 3ₙ and the second switch elements 4₁ to 4ₙ.

One terminal (source or drain) of each of the first switch elements 3 (3₁ to 3ₙ) is connected to a corresponding one of the first antifuse elements 1 (1₁ to 1ₙ), and the other terminal of each of the first switch elements 3 (3₁ to 3ₙ) is set to a ground potential. One terminal (source or drain) of each of the second switch elements 4 (4₁ to 4ₙ) is connected to a corresponding one of the second antifuse elements 2 (2₁ to 2ₙ), and the other terminal of each of the second switch elements 4 (4₁ to 4ₙ) is set to a ground potential. Each of the first switch elements 3 (3₁ to 3ₙ) and the second switch elements 4 (4₁ to 4ₙ) transitions from a non-conductive state (off state) to a conductive state (on state) when a value of a voltage supplied to a gate terminal thereof exceeds a threshold value.

A shift register 8 outputs selection signals S2 (S2₁ to S2ₘ, where m=2n) each for selecting a pair of a first antifuse element and a second antifuse element corresponding to two bits from among the first antifuse elements 1₁ to 1ₙ and the second antifuse elements 2₁ to 2ₙ. In this case, the pairs of first antifuse elements and second antifuse elements are assumed to be sequentially selected, for example, from the left side of an arrangement of the first antifuse elements 1₁ to 1ₙ and the second antifuse elements 2₁ to 2ₙ. The control circuit 7 sequentially selects, based on the selection signals S2, the pairs of first antifuse elements and second antifuse elements from among the first antifuse elements 1₁ to 1ₙ and the second antifuse elements 2₁ to 2ₙ as targets to which the voltages are to be applied. The selection signals S2₅ to S2ₘ are not shown in the figure.

The control circuit 7 includes control circuits 7₁ to 7ₙ each of which causes voltage applications to the corresponding pair of a first antifuse element 1 and a second antifuse element 2 to be alternately performed based on a pulse signal S1 and the selection signals S2 from the shift register 8. The pulse signal S1 is formed of a rectangular wave having fixed widths. The two-bit write operation is executed sequentially by the control circuits 7₁ to 7ₙ. In this case, it is assumed that the two-bit write operation is executed sequentially from the control circuit 7₁. The control circuits 7₃ to 7ₙ are not shown in the figure.

The control circuit 7₁ includes a logic circuit 5₁ that generates a voltage (gate voltage) for driving the first switch element 3₁, and a logic circuit 6₁ that generates a voltage (gate voltage) for driving the second switch element 4₁. In the same manner, the control circuits 7₂ to 7ₙ include logic circuits 5 (5₂ to 5ₙ) that generate voltages for driving the first switch element 3 (3₂ to 3ₙ) and logic circuits 6 (6₂ to 6ₙ) that generate voltages for driving the second switch elements 4 (4₂ to 4ₙ), respectively. The logic circuits 5₁ to 5ₙ have the same structure, and the logic circuits 6₁ to 6ₙ also have the same structure. Thus, specific operations are described below by taking the logic circuit 5₁ and the logic circuit 6₁ as examples.

The logic circuit 5₁ receives the pulse signal S1 as one input and the selection signal S2₁ as the other input, and when both inputs are at a high level (or "1"), supplies a high-level (positive) gate voltage to the gate terminal of the first switch element 3₁. In other words, under a state in which the first antifuse element 1₁ is selected by the selection signal S2₁, when the pulse signal S1 is at a high level, the logic circuit 5₁ supplies the high-level gate voltage to the gate terminal of the first switch element 3₁.

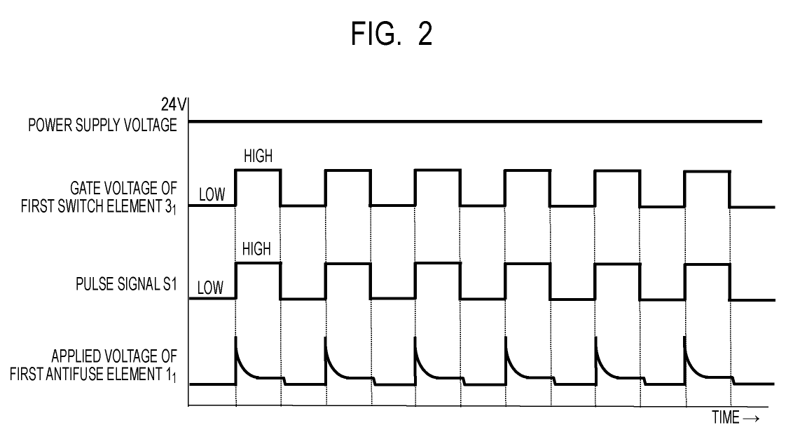

FIG. 2 is a timing chart for illustrating a relationship among the pulse signal S1, the gate voltage of the first switch element 3₁, and the applied voltage to the first antifuse element 1₁. In the example of FIG. 2, it is assumed that the power supply circuit 9 supplies a power supply voltage of 24 V. Under the state in which the first antifuse element 1₁ is selected, when the pulse signal S1 goes to a high level, the gate voltage of the first switch element 3₁ goes to a high level. As a result, the first switch element 3₁ is brought to an on state, and a voltage of 24 V is applied to the first antifuse element 1₁. As illustrated in FIG. 2, the height of a waveform of the applied voltage is largest at a time point at which the first switch element 3₁ is turned on, and then rapidly decreases. Through repeated turning on and off of the voltage application to the first antifuse element 1₁, a gate oxide film between two electrodes of the first antifuse element 1₁ undergoes dielectric breakdown, thereby bringing the first antifuse element 1₁ into a conductive state (written state of "1"). The first antifuse element 1₁ that has been made conductive has a low resistance. The first switch elements 3₂ to 3ₙ and the first antifuse elements 1₂ to 1ₙ have the same relationship as that illustrated in FIG. 2, and can be made conductive in the same procedure.

Meanwhile, the logic circuit 6₁ receives an inverted signal of the pulse signal S1 as one input and the selection signal S2₂ as the other input, and when both inputs are at a high level (or "1"), supplies a high-level (positive) voltage to the gate terminal of the second switch element 4₁. In other words, under a state in which the second antifuse element 2₁ is selected by the selection signal S2₂, when the pulse signal S1 is at a low level, the logic circuit 6₁ supplies the high-level voltage to the gate terminal of the second switch element 4₁.

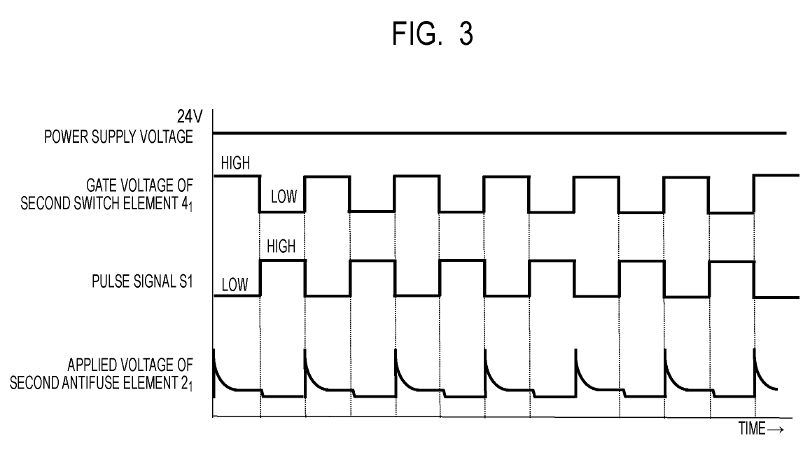

FIG. 3 is a timing chart for illustrating a relationship among the pulse signal S1, the gate voltage of the second switch element 4₁, and the applied voltage to the second antifuse element 2₁. In the example of FIG. 3, it is assumed that the power supply circuit 9 supplies a power supply voltage of 24 V. Under the state in which the second antifuse element 2₁ is selected, when the pulse signal S1 goes to a low level, the gate voltage of the second switch element 4₁ goes to a high level. As a result, the second switch element 4₁ is brought to an on state, and a voltage of 24 V is applied to the second antifuse element 2₁. As illustrated in FIG. 3, the height of a waveform of the applied voltage is largest at a time point at which the second switch element 4₁ is turned on, and then rapidly decreases. Through repeated turning on and off of the voltage application to the second antifuse element 2₁, a gate oxide film between two electrodes of the second antifuse element 2₁ undergoes dielectric breakdown, thereby bringing the second antifuse element 2₁ into a conductive state (written state of "1"). The second switch elements 4₂ to 4ₙ and the second antifuse elements 2₂ to 2ₙ have the same relationship as that illustrated in FIG. 3, and can be made conductive in the same procedure.

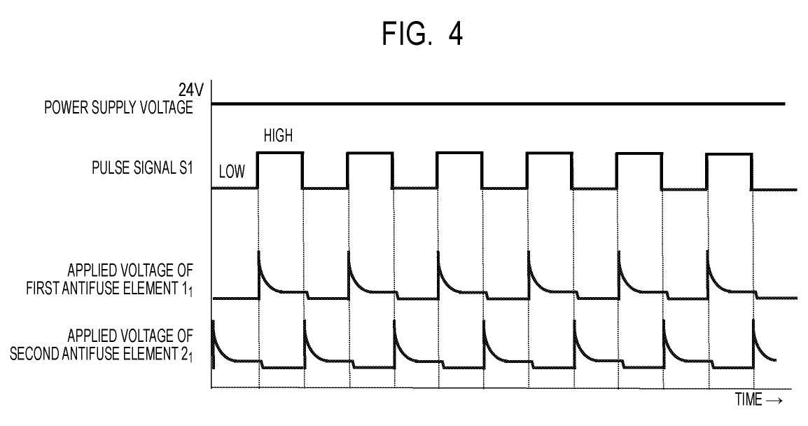

FIG. 4 is a timing chart for illustrating a relationship among the pulse signal S1, the applied voltage to the first antifuse element 1₁, and the applied voltage to the second antifuse element 2₁. During a high-level period (on period) of the pulse signal S1, under a state in which the first antifuse element 1₁ and the second antifuse element 2₁ are selected, the first switch element 3₁ is on, and the second switch element 4 is off. During a low-level period (off period) of the pulse signal S1, under the state in which the first antifuse element 1₁ and the second antifuse element 2₁ are selected, the first switch element 3₁ is off, and the second switch element 4₁ is on. When the pulse signal S1 is at a high level, a voltage is applied to the first antifuse element 1₁, and when the pulse signal S1 is at a low level, a voltage is applied to the second antifuse element 2₁. In this manner, the voltage application to the first antifuse element 1₁ and the voltage application to the second antifuse element 2₁ are exclusively alternately performed based on the pulse signal S1 (two-bit write operation). In the same manner, for the first antifuse elements 1₂ to 1ₙ and the second antifuse elements 2₂ to 2ₙ as well, the voltage applications to the corresponding pair of a first antifuse element and a second antifuse element selected by the selection signals S2₃ to S2ₘ are exclusively alternately performed.

The first antifuse elements 1 (1₁ to 1ₙ) and the second antifuse elements 2 (2₁ to 2ₙ) can be made conductive through the repeated turning on and off of the voltage application at a frequency of, for example, 6 MHz. In one embodiment, the number of times that the voltage application is turned on and off is about 10,000 on average, but due to individual differences among elements, some elements require about 60,000 times to achieve conduction. For that reason, in this embodiment, the number of times that the voltage application is turned on and off is set to the maximum of 60,000. However, the value of the number of times that the voltage application is turned on and off is merely an example, and is to be set as appropriate in consideration of the individual differences among antifuse elements.

The semiconductor storage device 10 according to this embodiment described above produces the following actions and effects.

Due to the individual differences among antifuse elements, in one embodiment, the number of times that the voltage is turned on and off required to make the antifuse element conductive may differ depending on the antifuse element. Thus, in a case of performing the two-bit write operation, one of the first antifuse element or the second antifuse element may become conductive first, causing a current to more easily flow into the antifuse element that has become conductive, and it may thereby become more difficult for a current required for conduction to flow into the other antifuse element. In data writing in the semiconductor storage device 10 according to this embodiment, the voltage application to the first antifuse element 1 and the voltage application to the second antifuse element 2 are exclusively alternately performed. Accordingly, even when the first antifuse element 1 becomes conductive first, it is possible to apply the voltage to the second antifuse element 2 to make the second antifuse element 2 conductive.

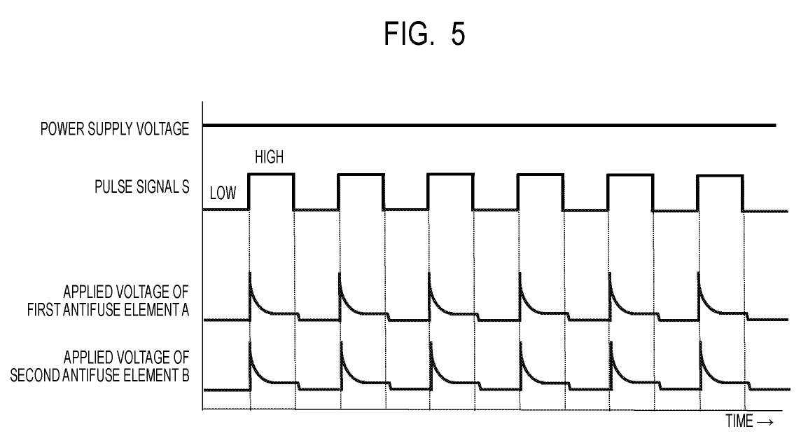

As a comparative example, FIG. 5 is a timing chart of a two-bit write operation in which a voltage application to a first antifuse element A and a voltage application to a second antifuse element B are simultaneously performed. During a high-level period (on period) of a pulse signal S, both the first antifuse element A and the second antifuse element B are in a selected state. When the pulse signal S is at a high level, a voltage is applied to each of the first antifuse element A and the second antifuse element B. For example, it is assumed that the first antifuse element A becomes conductive first. In this case, a current is caused to flow into the first antifuse element A that has become conductive first, and it becomes more difficult for a current required for conduction to flow into the second antifuse element B. As a result, the second antifuse element B cannot be made conductive, and a write error occurs.

In contrast, in the two-bit write operation illustrated in FIG. 4, even when the first antifuse element 1₁ becomes conductive first, during the low-level period (off period) of the pulse signal S1, the first switch element 3₁ is off, and the second switch element 4₁ is on. Thus, during the low-level period (off period) of the pulse signal S1, no current is caused to flow into the first antifuse element 1₁ that has become conductive, and a current required for conduction can be caused to flow into the second antifuse element 2₁. Accordingly, it is possible to suppress occurrence of a write error, and to provide a stable written state.

Further, with the semiconductor storage device 10 according to this embodiment, it is possible to increase a cycle rate through shortening of a write cycle time by performing the two-bit write operation. For example, compared to a one-bit write operation in which the first antifuse elements 1₁ to 1ₙ and the second antifuse elements 2₁ to 2ₙ are made conductive one by one from the left end, the cycle rate is increased twofold, thereby being able to improve productivity.

Data is read out from the semiconductor storage device 10, for example, one bit at a time. This method of reading out data is a well-known existing method, and hence a detailed description thereof is omitted herein.

Further, in one embodiment, the pulse signal S1 has a duty ratio of 50%. Thus, it is possible to equalize a period for the voltage application to the first antifuse element 1 and a period for the voltage application to the second antifuse element 2, and to achieve a more stable write operation.

Further, in the configuration illustrated in FIG. 1, the first switch elements 3 (3₁ to 3ₙ) may be provided between the power supply circuit 9 and the first antifuse elements 1 (1₁ to 1ₙ), respectively. In the same manner, the second switch elements 4 (4₁ to 4ₙ) may be provided between the power supply circuit 9 and the second antifuse elements 2 (2₁ to 2ₙ), respectively. Further, the first switch elements 3 (3₁ to 3ₙ) may be provided between the power supply circuit 9 and the first antifuse elements 1 (1₁ to 1ₙ), respectively, and the second switch elements 4 (4₁ to 4ₙ) may be provided between the power supply circuit 9 and the second antifuse elements 2 (2₁ to 2ₙ), respectively.

### Second Embodiment

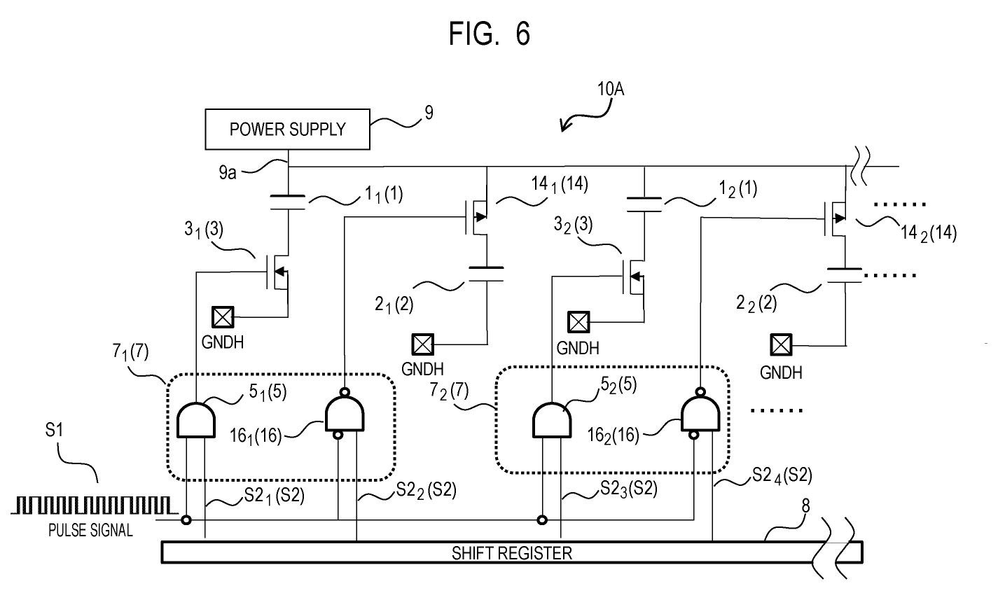

FIG. 6 is a schematic diagram for illustrating a configuration of a semiconductor storage device according to a second embodiment of the disclosure. A semiconductor storage device 10A according to this embodiment differs from the semiconductor storage device 10 according to the first embodiment in that the semiconductor storage device 10A includes second switch elements 14 (14₁ to 14ₙ) and logic circuits 16 (16₁ to 16ₙ) in place of the second switch elements 4 (4₁ to 4ₙ) and the logic circuits 6 (6₁ to 6ₙ). In one embodiment, the components other than the second switch elements 14 (14₁ to 14ₙ) and the logic circuits 16 (16₁ to 16ₙ) are the same as those in the first embodiment. The same components are denoted by the same reference symbols, and detailed descriptions thereof are omitted. The second switch elements 14₃ to 14ₙ and the logic circuits 16₃ to 16ₙ are not shown in the figure.

While the first switch elements 3₁ to 3ₙ are the n-type MOS switch elements, the second switch elements 14₁ to 14ₙ are p-type MOS (p-MOS) switch elements. One terminal (source or drain) of each of the second switch elements 14 (14₁ to 14ₙ) is connected to a corresponding one of the second antifuse elements 2 (2₁ to 2ₙ), and the other terminal of each of the second switch elements 14 (14₁ to 14ₙ) is set to a ground potential. Each of the second switch elements 14 (14₁ to 14ₙ) transitions from a non-conductive state (off state) to a conductive state (on state) when a value of a voltage supplied to a gate terminal thereof exceeds a threshold value.

The logic circuits 16 (16₁ to 16ₙ) generate voltages for driving the second switch elements 14 (14₁ to 14ₙ) based on an inverted signal of the pulse signal S1 and the selection signals S2 (S2₁ to S2ₘ), respectively. Specifically, the logic circuit 16₁ receives the inverted signal of the pulse signal S1 as one input and the selection signal S2₂ as the other input, and when both inputs are at a high level (or "1"), supplies a low-level (negative) voltage to the gate terminal of the second switch element 14₁. In other words, under a state in which the second antifuse element 2₁ is selected by the selection signal S2₂, when the pulse signal S1 is at a low level, the logic circuit 16₁ supplies the low-level voltage to the gate terminal of the second switch element 14₁. In the same manner as in the case of the logic circuit 16₁, under a state in which the second antifuse elements 2₂ to 2ₙ are selected, when the pulse signal S1 is at a low level, the logic circuits 16₂ to 16ₙ supply the low-level voltages to the gate terminals of the second switch elements 14₂ to 14ₙ, respectively.

In the semiconductor storage device 10A according to this embodiment, in the same manner as in the first embodiment, the two-bit write operation illustrated in FIG. 4 is performed. During the high-level period (on period) of the pulse signal S1, under the state in which the first antifuse element 1₁ and the second antifuse element 2₁ are selected, the first switch element 3₁ is on, and the second switch element 14₁ is off. During the low-level period (off period) of the pulse signal S1, under the state in which the first antifuse element 1₁ and the second antifuse element 2₁ are selected, the first switch element 3₁ is off, and the second switch element 14₁ is on. When the pulse signal S1 is at a high level, a voltage is applied to the first antifuse element 1₁, and when the pulse signal S1 is at a low level, a voltage is applied to the second antifuse element 2₁. In this manner, the voltage application to the first antifuse element 1₁ and the voltage application to the second antifuse element 2₁ are exclusively alternately performed based on the pulse signal S1. In the same manner, for the first antifuse elements 1₂ to 1ₙ and the second antifuse elements 2₂ to 2ₙ as well, the voltage applications to the corresponding pair of first antifuse element and second antifuse element selected by the selection signals S2₃ to S2ₘ are exclusively alternately performed.

The semiconductor storage device 10A according to this embodiment also produces the same actions and effects as those in the first embodiment by performing the above-mentioned two-bit write operation.

The semiconductor storage device 10 according to the first embodiment and the semiconductor storage device 10A according to the second embodiment that have been described above can be applied to a printing apparatus or a printing head.

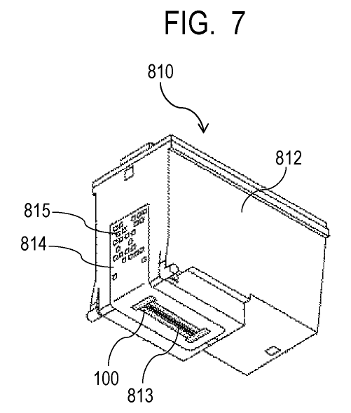

FIG. 7 is a perspective view of the printing head equipped with any one of the semiconductor storage device 10 or the semiconductor storage device 10A. A printing head 810 performs printing, for example, in accordance with an inkjet method, and is mounted to a carriage (not shown) of the printing apparatus. A carriage substrate for electrical connection to a contact pad of the printing head 810 is mounted to the carriage. A plurality of discharge ports 813 for discharging liquid are formed in a row in an element substrate 100. Various circuits (not shown) including an energy generating element for generating energy for discharging the liquid are formed in the element substrate 100. The element substrate 100 is electrically connected to a contact pad 815 for electrical connection to the carriage substrate through a flexible film wiring substrate 814.

The printing head 810 includes an ink tank 812. The ink tank 812 includes, for example, a fibrous or porous ink holding material (not shown), and holds ink by this ink holding material. The printing head 810 receives an electrical signal from the carriage substrate mounted to the carriage through the contact pad 815, and discharges the ink in accordance with the electrical signal. The printing head 810 illustrated in FIG. 7 is configured such that the element substrate 100 and the ink tank 812 are integrated, but can also be configured such that the ink tank is separable.

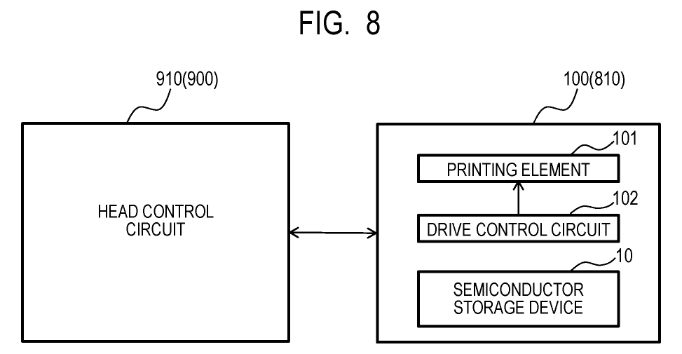

FIG. 8 is a schematic diagram for illustrating a configuration of the element substrate 100. The element substrate 100 is electrically connected to a head control circuit 910 of a printing apparatus 900 through the contact pad 815. The element substrate 100 includes a printing element (heater) 101 serving as the energy generating element, a drive control circuit 102 that controls drive of the printing element 101, and the semiconductor storage device 10 according to the first embodiment. The printing element 101 is provided to each of the discharge ports 813. The semiconductor storage device 10A according to the second embodiment may be used in place of the semiconductor storage device 10.

The head control circuit 910 controls operations of the printing head 810 (including operations of, for example, the printing element 101 and the semiconductor storage device 10). For example, when liquid is to be discharged from the printing head 810, the head control circuit 910 supplies drive data for driving each printing element 101 to the drive control circuit 102. The drive control circuit 102 controls the drive of each printing element 101 in accordance with the drive data. Further, when data is to be written to the semiconductor storage device 10, the head control circuit 910 supplies the pulse signal S1 and data for the two-bit write operation to the semiconductor storage device 10. The two-bit write operation of the semiconductor storage device 10 is as described in the first embodiment. Information relating to the printing head 810 is stored in the semiconductor storage device 10 as bit data. As the information relating to the printing head 810, various types of information such as a chip ID and a rank value for managing optimal discharging energy can be stored in the semiconductor storage device 10.

According to the disclosure, it is possible to provide the two-bit write operation which can suppress reduction in productivity and occurrence of a write error.

While the disclosure has been described with reference to embodiments, it is to be understood that the disclosure is not limited to the disclosed embodiments. The scope of the following claims is to be accorded the broadest interpretation so as to encompass all such modifications and equivalent structures and functions.

This application claims the benefit of Japanese Patent Application No. 2024-186544, filed October 23, 2024, which is hereby incorporated by reference herein in its entirety.

What is claimed is:

1. A storage device comprising:
a first antifuse element and a second antifuse element, the storage device being configured such that a supply line extending from a single power supply is branched into supply lines so that the respective supply lines are connected to the first antifuse element and the second antifuse element; and
a control circuit configured to cause a first voltage application to the first antifuse element and a second voltage application to the second antifuse element to be alternately performed.

2. The storage device according to claim 1, wherein the control circuit is further configured to receive an input of a pulse signal formed of a rectangular wave having fixed widths, apply a voltage to the first antifuse element when the pulse signal is at a high level, and apply a voltage to the second antifuse element when the pulse signal is at a low level.

3. The storage device according to claim 2, further comprising:
a first switch element connected in series to the first antifuse element; and
a second switch element connected in series to the second antifuse element,
wherein the power supply is connected to a ground potential terminal through the first antifuse element and the first switch element, and is connected to the ground potential terminal through the second antifuse element and the second switch element, and
wherein the control circuit is further configured to bring the first switch element to an on state and the second switch element to an off state when the pulse signal is at a high level, and bring the first switch element to an off state and the second switch element to an on state when the pulse signal is at a low level.

4. The storage device according to claim 3,
wherein the first switch element is provided between the first antifuse element and the ground potential terminal, and
wherein the second switch element is provided between the second antifuse element and the ground potential terminal.

5. The storage device according to claim 3,
wherein the first switch element is provided between the power supply and the first antifuse element, and
wherein the second switch element is provided between the power supply and the second antifuse element.

6. The storage device according to claim 3,
wherein the first switch element is provided between the first antifuse element and the ground potential terminal, and
wherein the second switch element is provided between the power supply and the second antifuse element.

7. The storage device according to claim 3,
wherein the first switch element is provided between the power supply and the first antifuse element, and
wherein the second switch element is provided between the second antifuse element and the ground potential terminal.

8. The storage device according to claim 2, wherein the pulse signal has a duty ratio of 50%.

9. The storage device according to claim 1, further comprising a shift register configured to output selection signals each for selecting a pair of a first antifuse element and a second antifuse element corresponding to two bits from among a plurality of the first antifuse elements and a plurality of the second antifuse elements,
wherein the control circuit is configured to sequentially select, based on the selection signals, the pairs of first antifuse elements and second antifuse elements from among the plurality of the first antifuse elements and the plurality of the second antifuse elements as targets to which voltages are to be applied.

10. A printing head comprising an element substrate in which a printing element for discharging liquid is formed,
wherein the element substrate includes a storage device,
wherein the storage device includes:
a first antifuse element and a second antifuse element, the storage device being configured such that a supply line extending from a single power supply is branched into supply lines so that the respective supply lines are connected to the first antifuse element and the second antifuse element; and
a control circuit configured to cause a first voltage application to the first antifuse element and a second voltage application to the second antifuse element to be alternately performed.

11. The printing head according to claim 10, wherein the storage device is configured to store data to be used for discharging the liquid.

12. A method for a storage device including a plurality of first antifuse elements and a plurality of second antifuse elements, the storage device being configured such that a supply line extending from a single power supply is branched into supply lines so that the respective supply lines are connected to the plurality of first antifuse elements and the plurality of second antifuse elements, the method comprising:
selecting a pair of a first antifuse element and a second antifuse element corresponding to two bits from among the plurality of first antifuse elements and the plurality of second antifuse elements; and
alternately performing voltage applications to the pair of the first antifuse element and the second antifuse element.

13. The method according to claim 12, further comprising:
outputting selection signals each for selecting a pair of a first antifuse element and a second antifuse element corresponding to two bits from among a plurality of the first antifuse elements and a plurality of the second antifuse elements; and
sequentially selecting, based on the selection signals, the pairs of first antifuse elements and second antifuse elements from among the plurality of the first antifuse elements and the plurality of the second antifuse elements as targets to which voltages are to be applied.

14. The method according to claim 12, further comprising:
receiving an input of a pulse signal formed of a rectangular wave having fixed widths; and
applying a voltage to the first antifuse element when the pulse signal is at a high level, and applying a voltage to the second antifuse element when the pulse signal is at a low level.

15. The method according to claim 14, wherein the pulse signal has a duty ratio of 50%.

16. The method according to claim 14, further comprising:
bringing the first switch element to an on state and the second switch element to an off state when the pulse signal is at a high level; and
bringing the first switch element to an off state and the second switch element to an on state when the pulse signal is at a low level,
wherein a first switch element is connected in series to the first antifuse element, and a second switch element connected in series to the second antifuse element, and
wherein the power supply is connected to a ground potential terminal through the first antifuse element and the first switch element, and is connected to the ground potential terminal through the second antifuse element and the second switch element.

17. The method according to claim 16,
wherein the first switch element is provided between the first antifuse element and the ground potential terminal, and
wherein the second switch element is provided between the second antifuse element and the ground potential terminal.

18. The method according to claim 16,
wherein the first switch element is provided between the power supply and the first antifuse element, and
wherein the second switch element is provided between the power supply and the second antifuse element.

19. The method according to claim 16,
wherein the first switch element is provided between the first antifuse element and the ground potential terminal, and
wherein the second switch element is provided between the power supply and the second antifuse element.

20. The semiconductor storage device according to claim 16,
wherein the first switch element is provided between the power supply and the first antifuse element, and
wherein the second switch element is provided between the second antifuse element and the ground potential terminal.
